(19) United States
(12) Patent Application Publication
(10) Pub. No.: US 2024/0042964 A1
(43) Pub. Date: Feb. 8, 2024

(54) FPKS Fingerprint Kill Switch

(71) Applicants: Taylor Autumn Thompson, Battle Ground, WA (US); Pamela Joanne Thompson, Battle Ground, WA (US); Devon Robert Thompson, Battle Ground, WA (US); Cody Seamus Thompson, Battle Ground, WA (US)

(72) Inventors: Taylor Autumn Thompson, Battle Ground, WA (US); Pamela Joanne Thompson, Battle Ground, WA (US); Devon Robert Thompson, Battle Ground, WA (US); Cody Seamus Thompson, Battle Ground, WA (US)

(21) Appl. No.: 17/876,513

(22) Filed: Jul. 28, 2022

(51) Int. Cl. B60R 25/25; H05K 5/02; B60R 25/04

(52) U.S. Cl. CPC B60R 25/252; H05K 5/0217; B60R 25/04; G06V 40/50

(57) ABSTRACT

1. Fingerprint Kill Switch (FPKS) is a kill switch for your vehicle that does not communicate with your ECU (engine control unit), instead it is directly wired to the ignition and starter wire of your vehicle. Fingerprint Kill Switch (FPKS) cuts off power to the starter until an authorized fingerprint(s) is submitted then and only then may you use the key and start the vehicle; however, the window to start your vehicle is only open for a short amount of time from (from 0.5 seconds to 30 seconds). If you are unable to start your vehicle in time, all you must do is input your fingerprint(s) again. Fingerprint Kill Switch (FPKS) operates differently from other products due to its simplicity, all it does is block vehicle ignition start up from anyone who does not have an authorized fingerprint(s), Fingerprint Kill Switch (FPKS) is unique due to its simplistic design that does not require communication with the onboard vehicle computers.

1. FKPS is a tool used to cut power to the ignition starter of a vehicle until an authorized fingerprint is presented. Without presenting your fingerprint, it removes the ability to have unauthorized individuals operating your vehicle. This tool makes the act of vehicle theft significantly harder to achieve. The objective of FPKS is to cut down the rate of automotive theft. With the FPSK tool present in your vehicle you can protect yourself from vehicle theft by simply turning off the vehicle. FPKS can also prevent uninsured drivers from using your vehicle by not being able to start the ignition with an authorized fingerprint.

### CROSS-REFERENCE TO RELATED APPLICATIONS

1. Not Applicable

### STATEMENT REGARDING FEDERALLY SPONSORED RESEARCH OR DEVELOPMENT

1. Not Applicable

### REFERENCE TO SEQUENCE LISTING, A TABLE, OR A COMPUTER PROGRAM LISTING COMPACT DISC APPENDIX

1. Not Applicable

### BACKGROUND OF THE INVENTION

1. FPKS applies to the automotive and security field industry respectively, as it is a device that is intended to minimize automotive theft. In 2020 more than 750,000 vehicles were stolen as stated by the National Highway Traffic Safety Administration. The objective of FPKS is to cut down the rate of automotive theft. With the FPSK tool present in your vehicle you can protect yourself from vehicle theft by simply turning off the vehicle. Without presenting your fingerprint, it removes the ability to have unauthorized individuals operating your vehicle furthermore minimizing automotive theft.

### BRIEF SUMMARY OF THE INVENTION

1. FKPS is a tool used to cut power to the ignition starter of a vehicle until an authorized fingerprint is presented. Without presenting your fingerprint, it removes the ability to have unauthorized individuals operating your vehicle. This tool makes the act of vehicle theft significantly harder to achieve. The objective of FPKS is to cut down the rate of automotive theft. With the FPSK tool present in your vehicle you can protect yourself from vehicle theft by simply turning off the vehicle. FPKS can also prevent uninsured drivers from using your vehicle by not being able to start the ignition with an authorized fingerprint.

### BRIEF DESCRIPTION OF THE SEVERAL VIEWS OF THE DRAWING

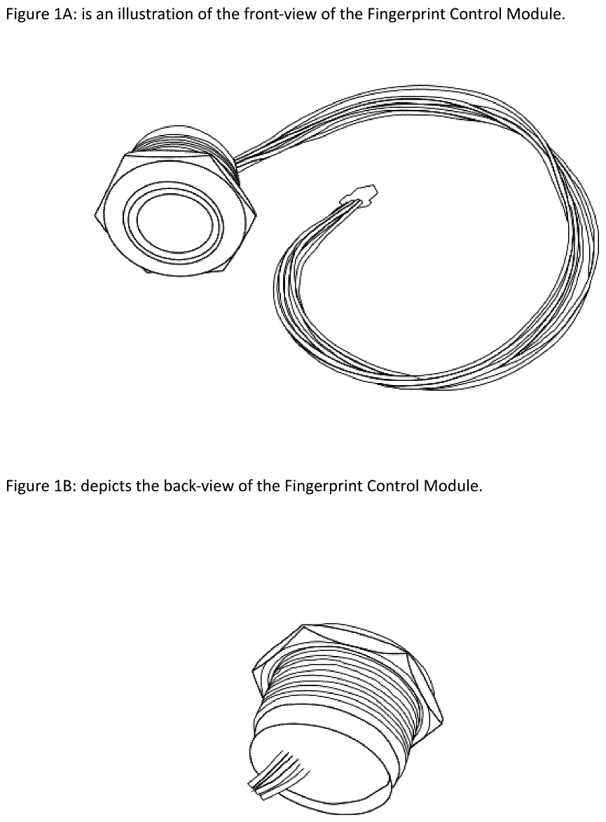

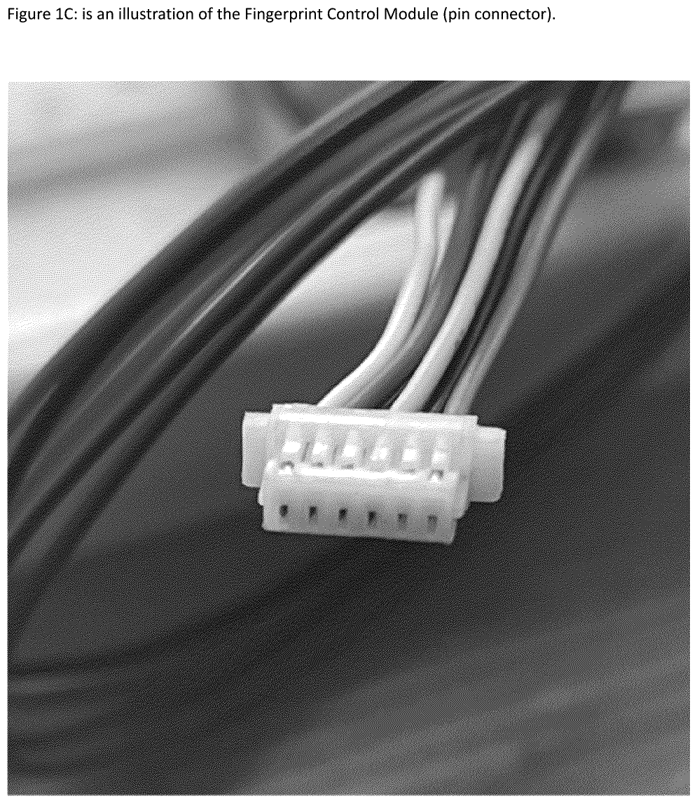

1. FIG. 1A is an illustration of the front view of the fingerprint control module.

2. FIG. 1B depicts the back view of the fingerprint control module.

3. FIG. 1C is an illustration of the fingerprint control module (pin connector).

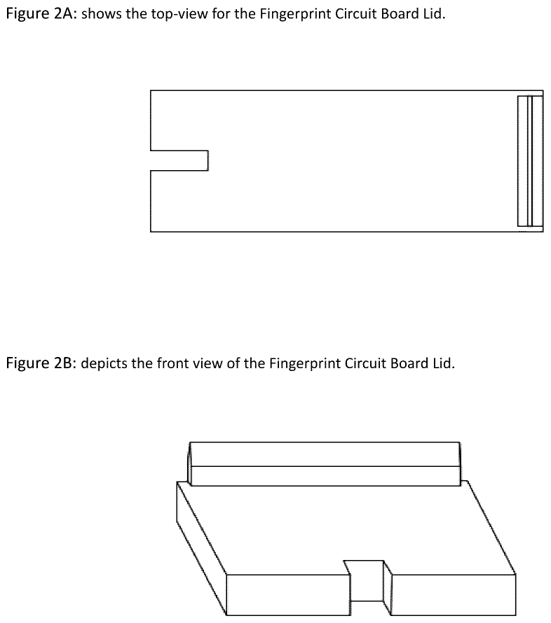

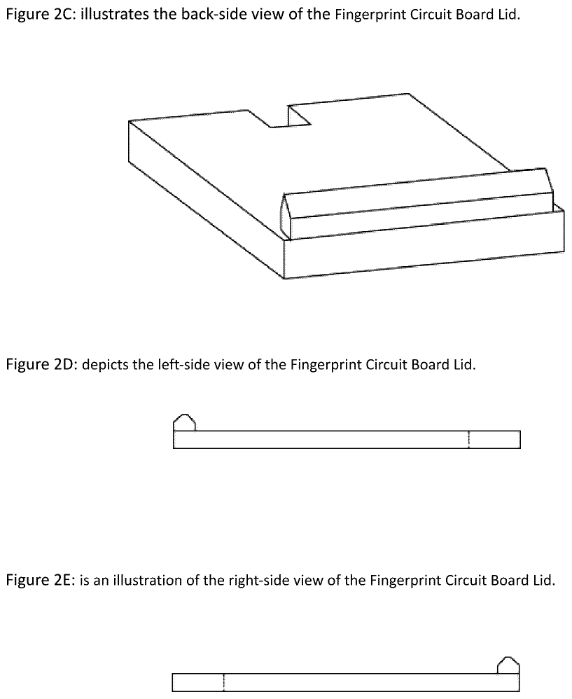

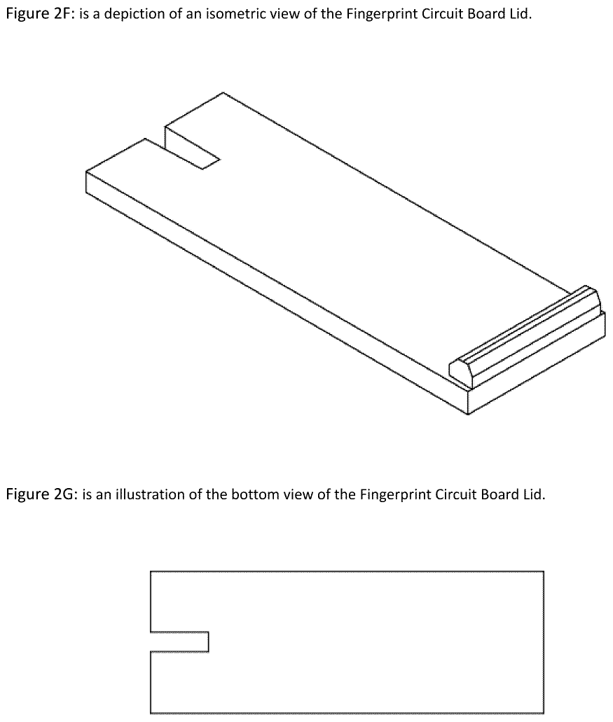

4. FIG. 2A shows the top view for the fingerprint circuit board lid.

5. FIG. 2B depicts the front view of the fingerprint circuit board lid.

6. FIG. 2C illustrates the back-side view of the fingerprint circuit board lid.

7. FIG. 2D depicts the left-side view of the fingerprint circuit board lid.

8. FIG. 2E is an illustration of the right-side view of the fingerprint circuit board lid.

9. FIG. 2F is a depiction of an isometric view of the fingerprint circuit board lid.

10. FIG. 2G is an illustration of the bottom view of the fingerprint circuit board lid.

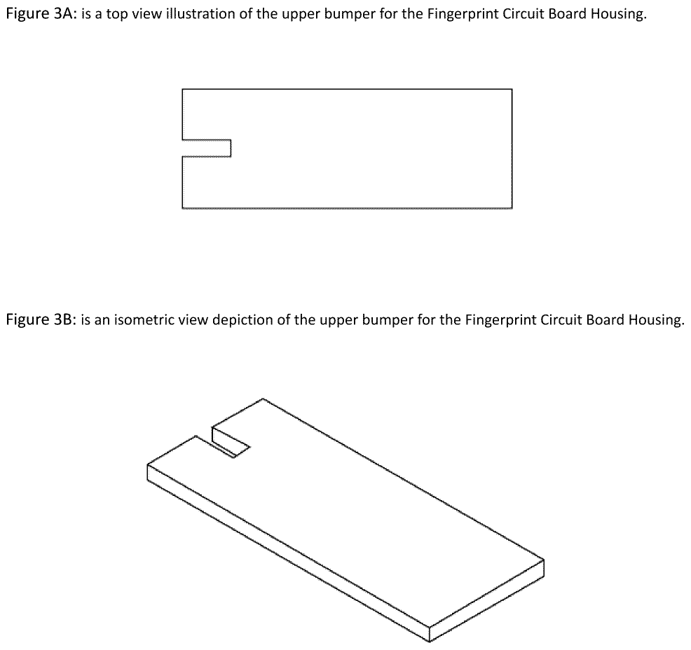

11. FIG. 3A is a top view illustration of the upper bumper for the fingerprint circuit board housing.

12. FIG. 3B is an isometric view depiction of the upper bumper for the fingerprint circuit board housing.

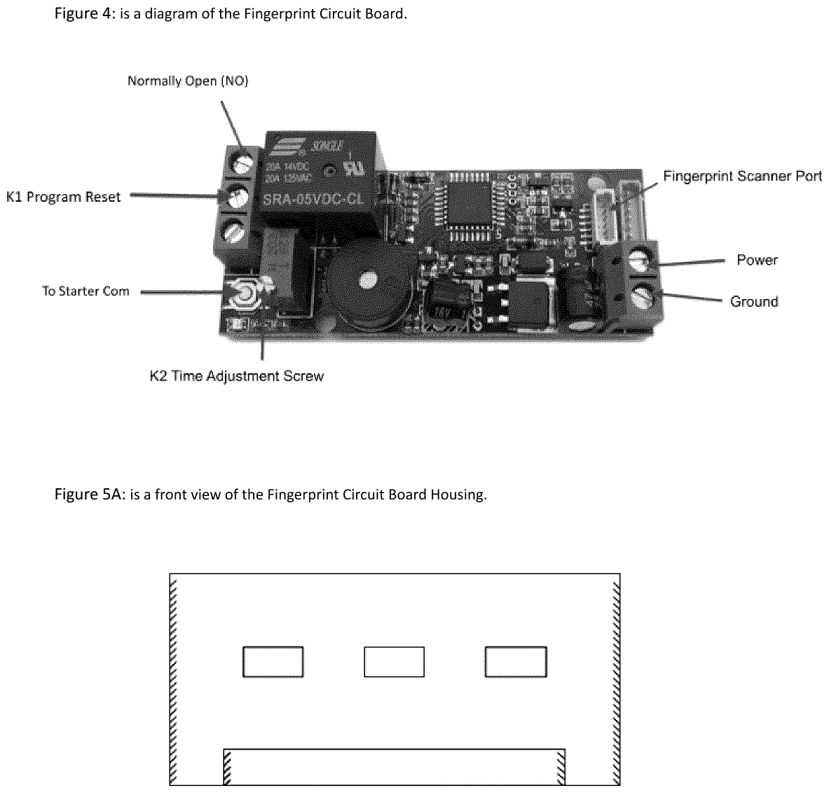

13. FIG. 4 is a diagram of the fingerprint circuit board.

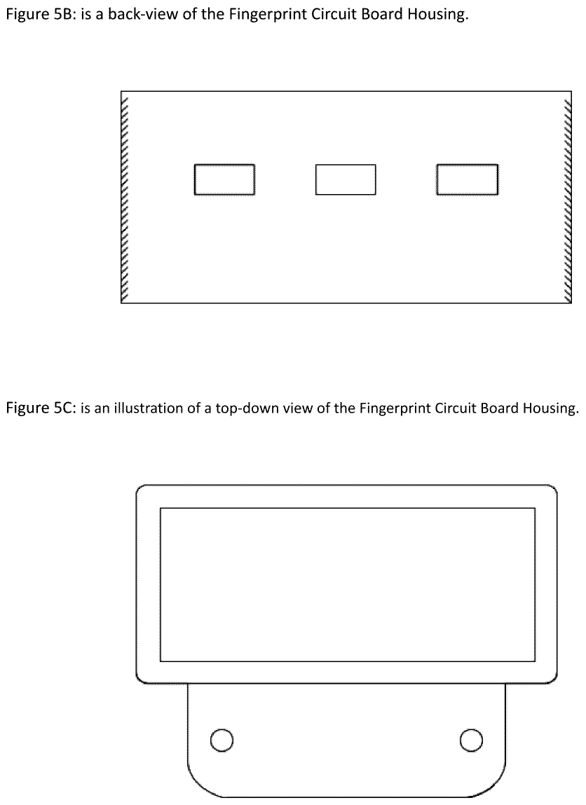

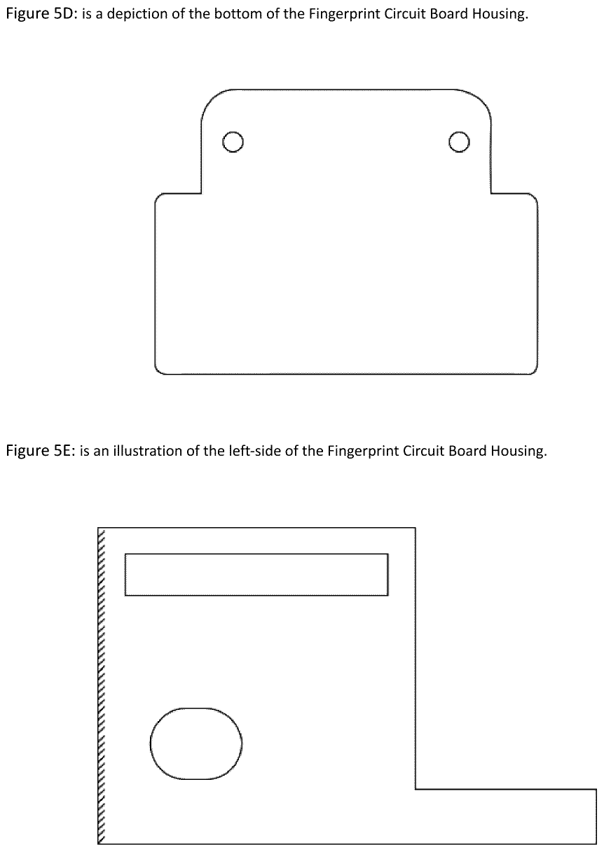

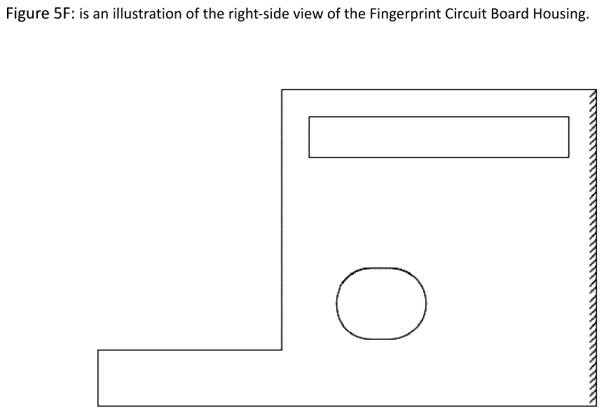

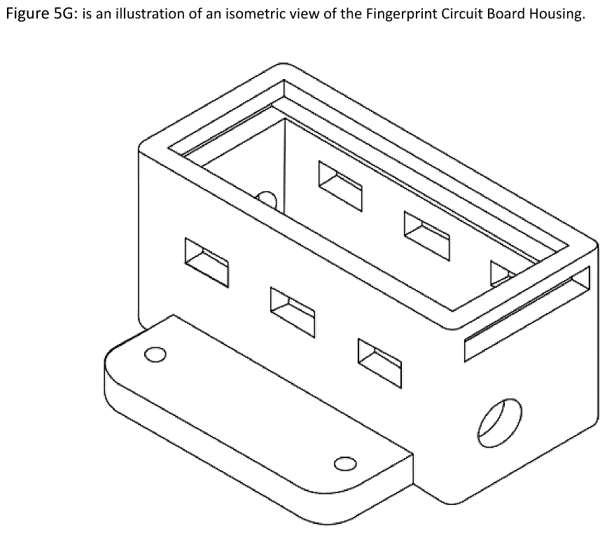

14. FIG. 5A is a front view of the fingerprint circuit board housing.

15. FIG. 5B is a back view of the fingerprint circuit board housing.

16. FIG. 5C is an illustration of a top-down view of the fingerprint circuit board housing.

17. FIG. 5D is a depiction of the bottom of the fingerprint circuit board housing.

18. FIG. 5E is an illustration of the left-side of the fingerprint circuit board housing.

19. FIG. 5F is an illustration of the right-side view of the fingerprint circuit board housing.

20. FIG. 5G is an illustration of an isometric view of the fingerprint circuit board housing.

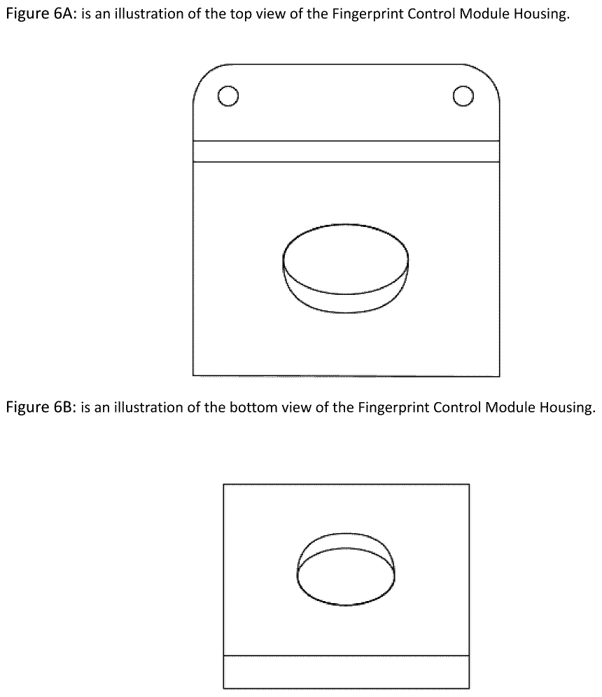

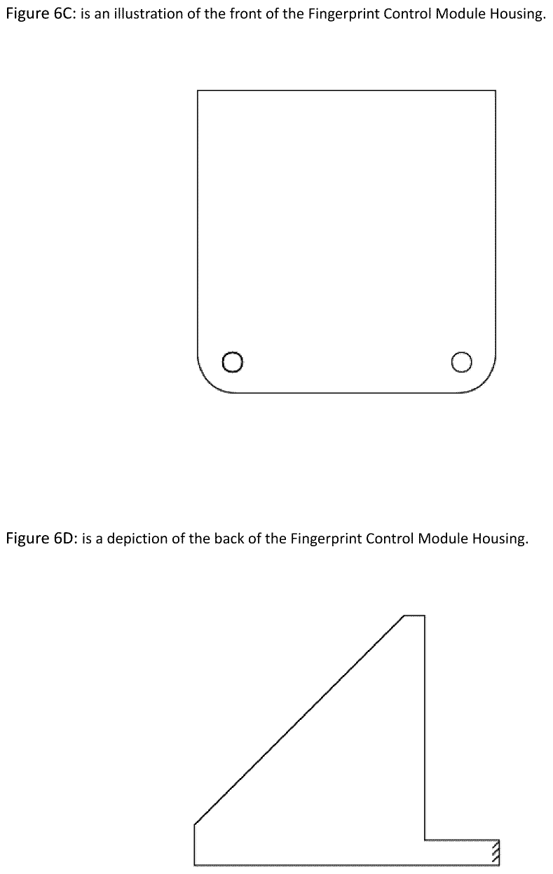

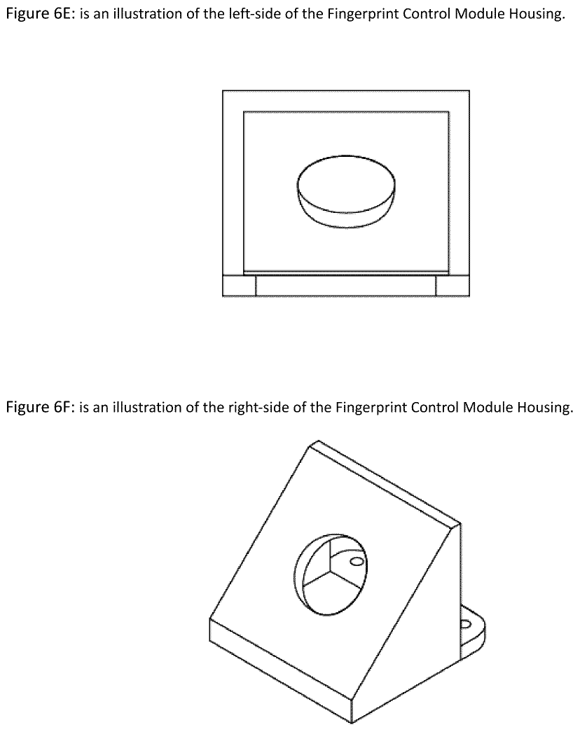

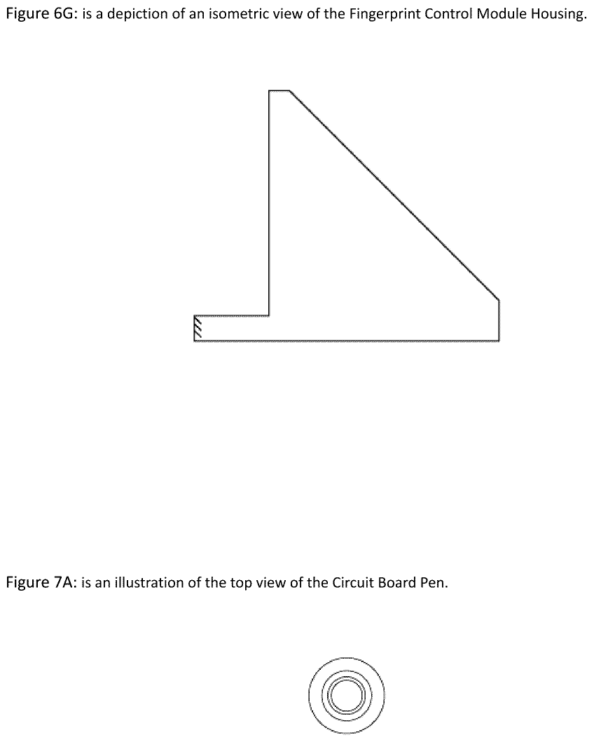

21. FIG. 6A is an illustration of the top view of the fingerprint control module housing.

22. FIG. 6B is an illustration of the bottom view of the fingerprint control module housing.

23. FIG. 6C is an illustration of the front of the fingerprint control module housing.

24. FIG. 6D is a depiction of the back of the fingerprint control module housing.

25. FIG. 6E is an illustration of the left-side of the fingerprint control module housing.

26. FIG. 6F is an illustration of the right-side of the fingerprint control module housing.

27. FIG. 6G is a depiction of an isometric view of the fingerprint control module housing.

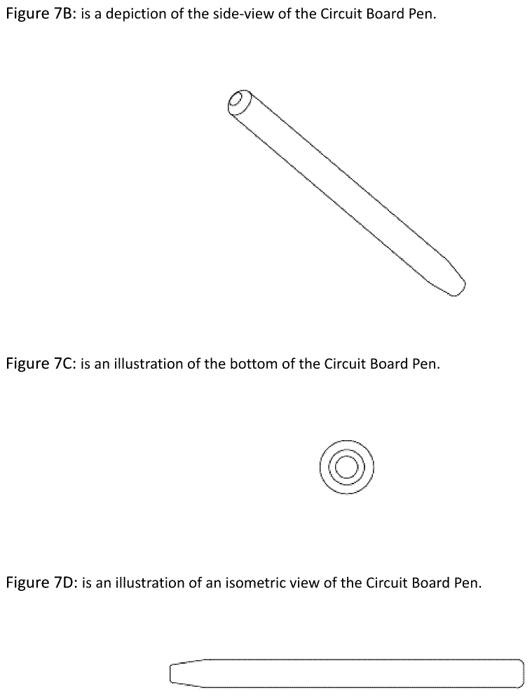

28. FIG. 7A is an illustration of the top view of the circuit board pen.

29. FIG. 7B is a depiction of the side-view of the circuit board pen.

30. FIG. 7C is an illustration of the bottom of the circuit board pen.

31. FIG. 7D is an illustration of an isometric view of the circuit board pen.

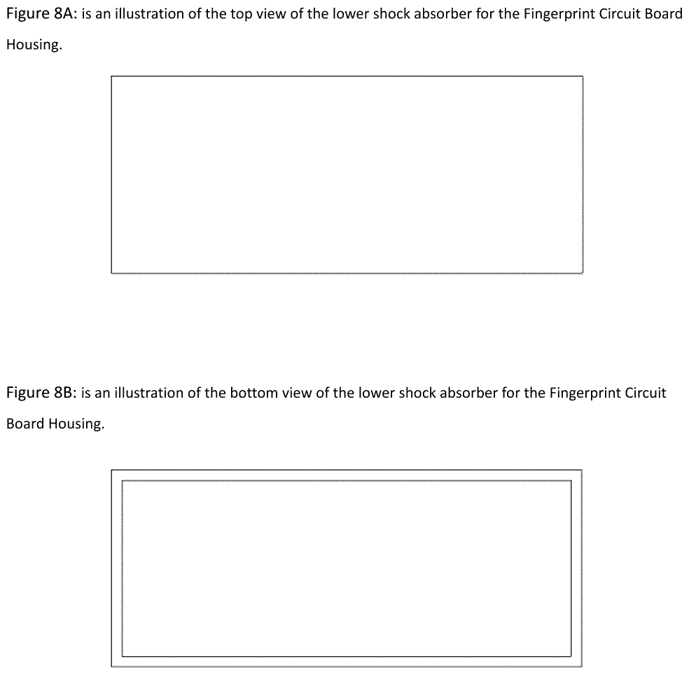

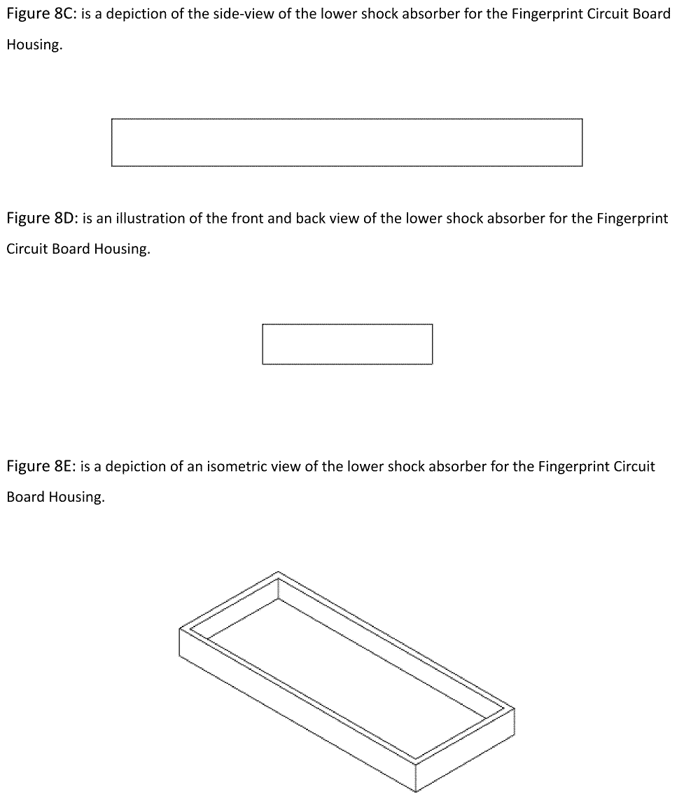

32. FIG. 8A is an illustration of the top view of the lower shock absorber for the fingerprint circuit board housing.

33. FIG. 8B is an illustration of the bottom view of the lower shock absorber for the fingerprint circuit board housing.

34. FIG. 8C is a depiction of the side-view of the lower shock absorber for the fingerprint circuit board housing.

35. FIG. 8D is an illustration of the front and back view of the lower shock absorber for the fingerprint circuit board housing.

36. FIG. 8E is a depiction of an isometric view of the lower shock absorber for the fingerprint circuit board housing.

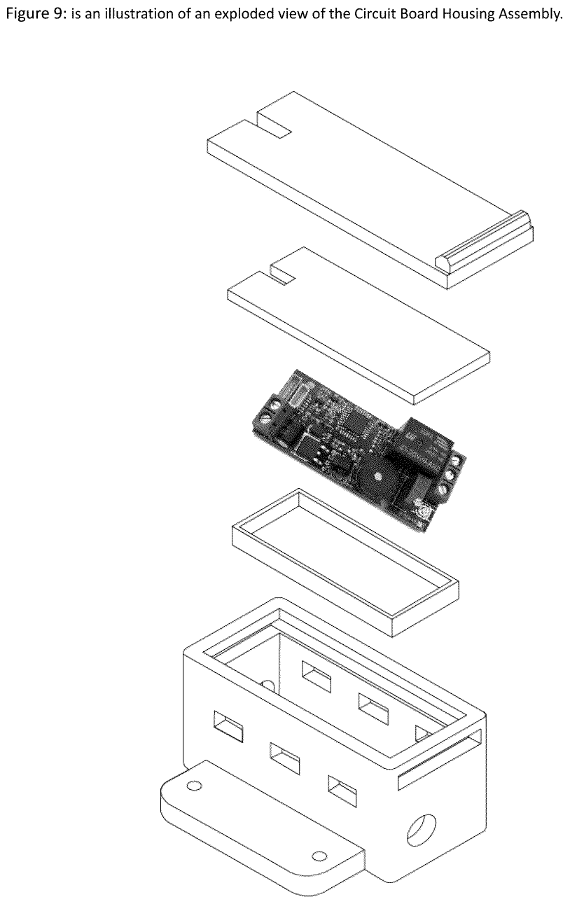

37. FIG. 9 is an illustration of an exploded view of the circuit board housing assembly.

### DETAILED DESCRIPTION OF THE INVENTION

1. FPKS is a kill switch that cuts power to the starter of the vehicle until a fingerprint programmed to the device is inputted; once that occurs power is restored for a short window of time so that the keys can be inserted, and the vehicle can be started. The hardware such as the circuit board housing, fingerprint control module housing, control module lid, and pen are all 3D printed using a 1.75 mm (about 0.07 in) PLA. The Upper and Lower Shock Absorbers are also 3D printed using a Carbon Fiber Nylon Blend Filament. FPKS is unique to its few competitors due to its simplicity in functionality, while other products communicate with the vehicles ECU (engine control module); FPKS works directly off power after the fingerprints are programmed in.

The following are steps for installing FPKS scanner into a vehicle
Step 1: decide on a location to install FPKS.
Step 2: decide whether you are going to use the provided remote mounting box or drill your own 23.5 mm (about 0.93 in) hole in your vehicle.
Step 3: locate a secure location within 6-7 inches of the desired installation location to mount the Circuit Board Housing.
Step 4: install the Lower Shock Absorber into the Circuit Board Housing.
Step 5: install the Circuit Board Housing into the vehicle in the chosen location. Using the included diagram (see FIG. 4.) locate ground port on Circuit Board Housing. Afterwards ground the system securely to metal. Using the same diagram (see FIG. 4.) locate a permanent power source or run a new line from the vehicle battery's positive terminal to the connect terminal.
Step 6: plug in the Fingerprint Scanner into the correct port of the Circuit Board.
Step 7: test to check the function of the scanner, upon checking you should receive the blue ring of approval from the scanner; if you receive the blue ring the scanner is functioning properly.
Step 9: locate the wire from your ignition to your starter. Near the area of your desired installation location, mark both the starter side and the ignition side of the wires.
Step 9: disconnect the battery.
Step 10: using diagram 4 (see FIG. 4.) locate the NO (Normally Open). Depending on the Installation location splice the appropriate length of wire, from the NO (Normally Open) slot on the Circuit Board to the starter side of the wire.
Step 11: using the same diagram locate COM (Common) Depending on the installation location splice appropriate length of wire from the COM (Common) slot on the Circuit Board ignition wire.
Step 12: Next is to program the FPKS tool, the list is as follows.

### Instructions for Operating the Control Circuit Board:

Step 1: register the Administrator Fingerprint Press the Set button briefly, a blue indicator light will quickly flash, and the system will enter a register state, repeatedly enter the fingerprint(s) which will be the Administrator fingerprint until you hear the meaning that the admin fingerprint has been set.
Step 2: User Fingerprint registration: Activate FPKS by holding the Administration Fingerprint on the Fingerprint Control Module until you hear music, then using a chosen Fingerprint press the Fingerprint Control Module until you hear music meaning fingerprint registration is successful. Multiple fingerprints can be registered while the system is in a registered state. Once the desired number of fingerprint(s) have been registered, wait a few seconds to exit the registration state.
Step 3: User fingerprint deletion: Hold Administration fingerprint on the Fingerprint Module for about (12 seconds) or until you hear “Di-” and then music, meaning that the User Fingerprint has been deleted.
Step 4: Restoring Factory Defaults: Press and hold the set button until you hear a “Di-” long beep and music, meaning that Factory Settings has been restored.
Step 5: Set Relay Time: Rotate the (K2 Screw) counterclockwise to set the relay's closing time from 0.5 seconds to 30 seconds.
Step 6: Usage: Press your fingerprint on the Fingerprint Control Module to start the vehicle, the relay will close after the fingerprint is authenticated. The closing is determined by time set by (K2 Screw) adjustment.
Step 7: After FPKS is programmed, install the Upper Shock Absorber (see FIGS. 8A through 8E), and the Circuit Board Housing Lid (see FIGS. 2A through 2G).
Step 8: After FPKS is fully installed, hide all the wires with the provided Wire Loom.

1: Ghost Specialties Enterprise LLC owns all rights to Fingerprint Kill Switch (FPKS) tool.

2: Ghost Specialties Enterprise LLC owns all rights to Fingerprint Kill Switch (FPKS) installation instructions for installing Fingerprint Kill Switch (FPKS) scanner into a vehicle.

3: Ghost Specialties Enterprise LLC owns all rights to Fingerprint Kill Switch (FPKS) installation instructions for operating the control circuit board.

4: Ghost Specialties Enterprise LLC owns all rights to Fingerprint Kill Switch (FPKS). FPKS is a tool used to cut power to the ignition starter of the vehicle until an authorized fingerprint is presented. This tool makes the act of vehicle theft significantly harder to achieve.

5: Ghost Specialties Enterprise LLC owns all rights to Fingerprint Kill Switch (FPKS) The hardware such as the circuit board housing, Fingerprint control module housing, control module lid, and pen are all 3D printed using a 1.75 mm (about 0.07 in) PLA. The Upper and lower shock absorbers are also 3D printed using a Carbon Fiber Nylon Blend Filament.

6: Ghost Specialties Enterprise LLC owns al rights to Fingerprint Kill Switch (FPKS) design schematics and layouts of the operating system.

1: Inventor of Fingerprint Kill Switch (FPKS) Taylor Autumn Thompson, U.S. Citizen, 22100 NE 237th Cir. Battle Ground WA 98604. Own rights to Fingerprint Kill Switch (FPKS).

2: Inventor of Fingerprint Kill Switch (FPKS) Ghost Specialties Enterprise LLC/Owner: Pamela Joanne Thompson, U.S. Citizen, 22100 NE 237th Cir. Battle Ground WA 98604. Owns the rights to Fingerprint Kill Switch (FPKS). Owns all rights to the installation instructions for installing Fingerprint Kill Switch (FPKS) scanner in a vehicle. Installation Instructions for operating the control circuit board, the circuit board housing, fingerprint control module housing, control module lid and pen are also 3D printed using a Carbon Fiber Nylon Blend Filament. Own the design schematics and layouts of the operating system

3: Inventor of Fingerprint Kill Switch (FPKS) Ghost Specialties Enterprise LLC Owner: Devon Robert Thompson U.S. Citizen, 22100 NE 237th Cir. Battle Ground WA 98604 owns all rights to the Fingerprint Kill Switch (FPKS).

4: Inventor of Fingerprint Kill Switch (FPKS) Cody Seamus Thompson, U.S. Citizen, 22100 NE 237TH Circle, Battle Ground, WA 98604. Owns rights to Fingerprint Kill Switch (FPKS).
